(19) United States
(12) Patent Application Publication
(10) Pub. No.: US 2025/0072271 A1
(43) Pub. Date: Feb. 27, 2025

(54) APPARATUS FOR MANUFACTURING DISPLAY DEVICE, METHOD FOR MANUFACTURING DISPLAY DEVICE, AND DISPLAY DEVICE

(71) Applicant: Samsung Display Co., LTD., Yongin-si (KR)

(72) Inventor: Ho Yun BYUN, Yongin-si (KR)

(21) Appl. No.: 18/645,176

(22) Filed: Apr. 24, 2024

(30) Foreign Application Priority Data
Aug. 22, 2023 (KR) 10-2023-0109890

(51) Int. Cl. H10K 71/13; H10K 59/80

(52) U.S. Cl. CPC H10K 71/135; H10K 59/8722; H10K 59/8792

(57) ABSTRACT

An apparatus for manufacturing a display device includes: a stage; a mold on the stage and including a first mold and a second mold surrounded by the first mold; a discharge head configured to discharge ink; a light irradiation part configured to irradiate light toward the stage; and a fixing device configured to fix the mold.

### CROSS-REFERENCE TO RELATED APPLICATION

The present application claims priority to and the benefit of Korean Patent Application No. 10-2023-0109890, filed on Aug. 22, 2023, in the Korean Intellectual Property Office, the entire disclosure of which is incorporated herein by reference.

### BACKGROUND

### 1. Technical Field

Aspects of some embodiments of the present disclosure relate to an apparatus for manufacturing a display device, a method for manufacturing a display device, and a display device.

### 2. Description of the Related Art

As the information society develops, consumer demand for display devices for displaying images has increased and diversified. Display devices may be, for example, flat panel display devices such as liquid crystal displays (LCDs), field emission displays (FEDs), or light emitting displays (LEDs). A light emitting display device may include an organic light emitting display device including organic light emitting diode elements operating as light emitting elements or a light emitting diode display device including inorganic light emitting diode elements such as light emitting diodes (LEDs) operating as light emitting elements.

A display device may include a cover window in order to protect a display panel. The cover window may be attached to the display panel through an optical clear adhesive. The optical clear adhesive may be applied onto the display panel through an application method using an inkjet facility, an application method using a roller, or the like.

The above information disclosed in this Background section is only for enhancement of understanding of the background and therefore the information discussed in this Background section does not necessarily constitute prior art.

### SUMMARY

Aspects of some embodiments of the present disclosure include an apparatus for manufacturing a display device and a method for manufacturing a display device in which a mold is relatively easily removed.

Aspects of some embodiments of the present disclosure may also include an apparatus for manufacturing a display device, a method for manufacturing a display device, and a display device in which reliability of an adhesive member may be relatively improved.

However, aspects of embodiments according to the present disclosure are not restricted to those set forth herein. The above and other aspects of some embodiments of the present disclosure will become more apparent to one of ordinary skill in the art to which the present disclosure pertains by referencing the detailed description of some embodiments of the present disclosure given below.

According to some embodiments of the present disclosure, an apparatus for manufacturing a display device includes: a stage, a mold on the stage and including a first mold and a second mold surrounded by the first mold, a discharge head configured to discharge ink, a light irradiation part configured to irradiate light toward the stage, and a fixing device configured to fix the mold.

According to some embodiments, the second mold is an island-type mold spaced apart from the first mold.

According to some embodiments, the mold includes at least one of a silicone-based material or a fluorine-based material.

According to some embodiments, the mold includes at least one of polydimethylsiloxane (PDMS) or polytetrafluoroethylene (PTFE).

According to some embodiments, the mold includes at least one of metal, glass, or plastic, and a mold release agent is applied to at least one side surface of the mold.

According to some embodiments, the fixing device includes at least one of a vacuum suction chuck or an electrostatic chuck.

According to some embodiments, the mold includes a conductive material.

According to some embodiments, the fixing device comprises, a first fixing device fixing the first mold, a second fixing device fixing a target substrate, and a third fixing device fixing the second mold.

According to some embodiments, the target substrate includes a through hole, and the third fixing device is configured to move inside the through hole.

According to some embodiments, at least one of an inner side surface of the first mold or a side surface of the second mold is an inclined surface of a reverse-tapered shape.

According to some embodiments, a length of a lower surface of the second mold is greater than or equal to a length of a through hole of a target substrate.

According to some embodiments, a height of the first mold is greater than a height of the second mold.

According to some embodiments of the present disclosure, in a method for manufacturing a display device, the method includes: fixing a display panel on a stage and fixing a first mold to an outer side of the display panel, arranging a second mold on a through hole of the display panel and fixing the second mold, forming an adhesive member by applying an adhesive material onto the display panel and temporarily hardening the applied adhesive material, and removing the first mold and the second mold.

According to some embodiments, the method for manufacturing a display device may further comprise forming a light blocking member by applying a light blocking material onto the display panel and hardening the applied light blocking material.

According to some embodiments, the light blocking material is applied along an outer side of the display panel.

According to some embodiments, in the fixing of the second mold, a fixing device moves inside the through hole to fix the second mold.

According to some embodiments of the present disclosure, a display device includes: a display panel, an upper member on the display panel, and an adhesive member between the display panel and the upper member to attach the display panel and the upper member to each other, wherein the adhesive member includes a through hole penetrating through at least a portion of the adhesive member, and a side surface of the through hole is an inclined surface.

According to some embodiments, the through hole has a reverse-tapered shape.

According to some embodiments, the adhesive member further includes a light blocking member arranged along an outer side of the adhesive member.

According to some embodiments, the light blocking member is between the display panel and the upper member.

With an apparatus for manufacturing a display device and a method for manufacturing a display device according to some embodiments of the present disclosure, a mold may be relatively easily removed.

With the apparatus for manufacturing a display device and the method for manufacturing a display device according to some embodiments of the present disclosure, reliability of an adhesive member may be relatively improved.

The characteristics of embodiments according to the present disclosure are not limited to the aforementioned characteristics, and various other characteristics are included in embodiments according to the present disclosure.

### BRIEF DESCRIPTION OF THE DRAWINGS

The above and other aspects and features of some embodiments of the present disclosure will become more apparent by describing in more detail aspects of some embodiments thereof with reference to the attached drawings, in which:

FIG. 1 is a plan view illustrating a display device according to some embodiments;

FIG. 2 is a cross-sectional view taken along the line X1-X1′ of FIG. 1;

FIG. 3 is a perspective view illustrating an adhesive member according to some embodiments;

FIG. 4 is a cross-sectional view taken along the line X2-X2′ of FIG. 3;

FIG. 5 is a cross-sectional view illustrating an example of a display panel according to some embodiments;

FIG. 6 is a cross-sectional view illustrating a display device according to some embodiments;

FIG. 7 is a plan view illustrating an adhesive member according to some embodiments;

FIG. 8 is a perspective view illustrating an apparatus for manufacturing a display device according to some embodiments;

FIG. 9 is a cross-sectional view taken along the line X3-X3′ of FIG. 8;

FIG. 10 is a perspective view illustrating a stage according to some embodiments;

FIG. 11 is a cross-sectional view taken along the line X4-X4′ in FIG. 9;

FIG. 12 is a cross-sectional view illustrating an operating state of the apparatus for manufacturing a display device according to some embodiments;

FIG. 13 is a flowchart illustrating aspects of a method for manufacturing a display device according to some embodiments;

FIG. 14 is a cross-sectional view illustrating further details of the operation S100 of FIG. 13;

FIG. 15 is a cross-sectional view illustrating further details of the operation S200 of FIG. 13;

FIG. 16 is a cross-sectional view illustrating further details of the operation S300 of FIG. 13;

FIG. 17 is a cross-sectional view illustrating further details of the operation S400 of FIG. 13;

FIG. 18 is a cross-sectional view illustrating further details of the operation S500 of FIG. 13;

FIG. 19 is a cross-sectional view illustrating further details of the operation S600 of FIG. 13;

FIG. 20 is a cross-sectional view illustrating further details of the operation S700 of FIG. 13;

FIG. 21 is a flowchart illustrating aspects of a method for manufacturing a display device according to some embodiments;

FIG. 22 is a cross-sectional view illustrating further details of the operation S500_1 of FIG. 21; and

FIG. 23 is a cross-sectional view illustrating further details of the operation S500 of FIG. 21.

### DETAILED DESCRIPTION

Aspects of some embodiments of the present disclosure will now be described more fully hereinafter with reference to the accompanying drawings, in which aspects of some embodiments of the present disclosure are shown. Embodiments according to the present disclosure may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, aspects of some embodiments of the present disclosure will be described in more detail with reference to the accompanying drawings.

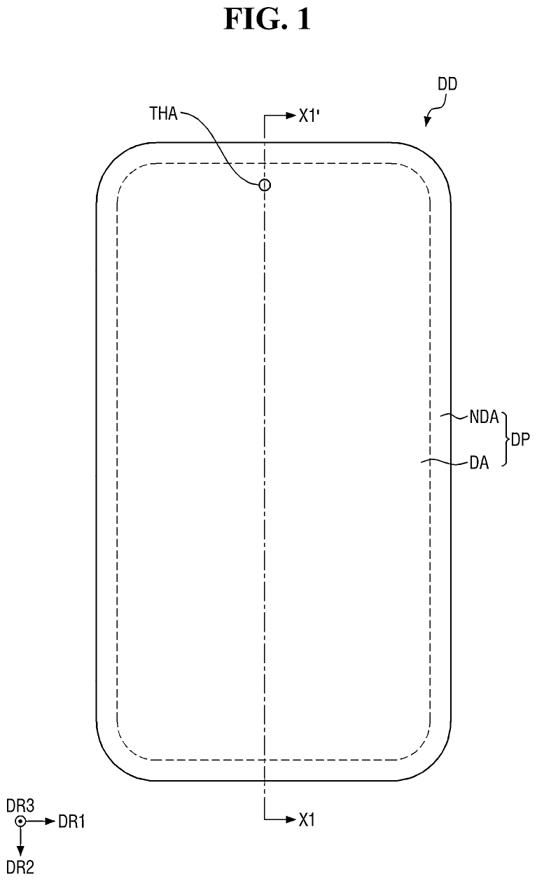

FIG. 1 is a plan view illustrating a display device according to some embodiments.

Referring to FIG. 1, a display device DD according to some embodiments is a device that displays moving images (e.g., video images) or still images (e.g., static images), and may be used as a display screen of various products such as televisions, laptop computers, monitors, billboards, and the Internet of Things (IOT) as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs). The display device DD may be any one of an organic light emitting display, a liquid crystal display, a plasma display panel, a field emission display, an electrophoretic display, an electro-wetting display, a quantum dot light emitting display, and/or a micro light emitting diode (LED) display. Hereinafter, embodiments according to the present disclosure will mainly described in the context of the display device DD being an organic light emitting display, but embodiments according to the present disclosure are not limited thereto.

The display device DD may have various shapes. According to some embodiments, the display device DD may have an approximately rectangular shape on a plane along a first direction DR1 and a second direction DR2 (e.g., in a plan view, or in a view taken from a direction normal or perpendicular to a display surface of the display device DD and/or a plane defined by the first direction DR1 and the second direction DR2). For example, the display device DD may include two first sides extending in the first direction DR1 and two second sides extending in the second direction DR2 on the plane. According to some embodiments, the first side may be shorter than the second side, but embodiments according to the present disclosure are not limited thereto. For example, according to some embodiments, the second side may be shorter than the first side, the first and second sides may be equal in length, and ore the shape of the display device DD may be generally polygonal.

In the drawings, the first direction DR1 and the second direction DR2 are horizontal directions, respectively, and cross each other. For example, the first direction DR1 and the second direction DR2 may be orthogonal to each other. In addition, a third direction DR3 may be a perpendicular direction crossing, for example, orthogonal to, the first direction DR1 and the second direction DR2. One sides of the first to third directions DR1, DR2, and DR3 as used herein may refer to directions indicated by arrows in the drawings, and the other sides of the first to third directions DR1, DR2, and DR3 as used herein may refer to directions opposite to the directions indicated by the arrows. When only the first to third directions DR1, DR2, and DR3 are specified without mentioning one sides or the other side of the first to third directions DR1, DR2, and DR3, they may included both one sides and the other sides.

The display device DD may have angled corners or rounded corners. For example, a corner where the first side and the second side of the display device DD meet may be right-angled or rounded.

The shape of the display device DD in plan view is not limited to the illustrated shape, and may also be a circular shape, an elliptical shape, or other shapes. In addition, embodiments in which a display surface of the display device DD including a display area DA is flat has been illustrated in FIG. 1, but embodiments according to the present disclosure are not limited thereto. For example, the display surface of the display device DD may also include a curved surface at least in a portion thereof.

The display device DD may include a display area DA and a non-display area NDA positioned around (e.g., in a periphery or outside a footprint of) the display area DA.

The display area DA may include pixels for displaying images. The display area DA may include not only the pixels, but also scan lines, data lines, and power lines connected to the pixels.

According to some embodiments, a transmissive hole area THA corresponding to a camera or the like may be located in the display area DA. As an example, the transmissive hole area THA may be a non-pixel area in which pixels are not located or a low-resolution area in which the pixels are arranged or formed at a low resolution.

The non-display area NDA may be located on at least one side of the display area DA and may partially or entirely surround the display area DA. In the non-display area NDA, lines, pads, and/or at least one driving circuit electrically connected to the pixels of the display area DA may be located.

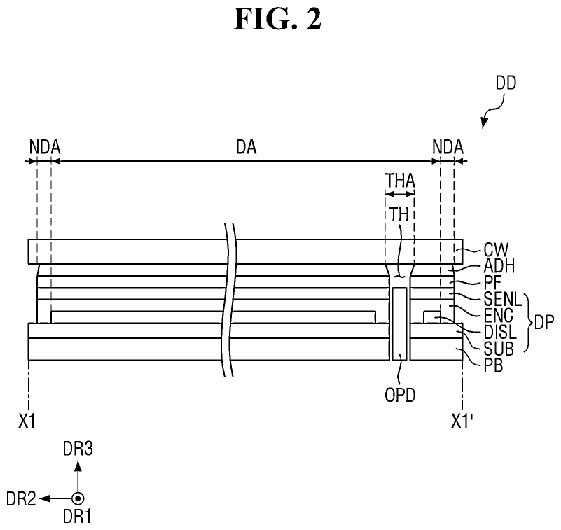

FIG. 2 is a cross-sectional view taken along the line X1-X1′ of FIG. 1.

Referring to FIG. 2 in addition to FIG. 1, the display device DD according to some embodiments may include a display panel DP, a polarizing film PF, an adhesive member ADH, a cover window CW, and a panel lower cover PB. The display panel DP may include a substrate SUB, a display layer DISL, an encapsulation layer ENC, and a sensor electrode layer SENL.

The substrate SUB may include a transparent material. For example, the substrate SUB may include a transparent insulating material such as glass or quartz. The substrate SUB may be a rigid substrate. However, the substrate SUB is not limited thereto, and may include plastic such as polyimide, and may have flexible characteristics so as to be curved, bent, folded, or rolled.

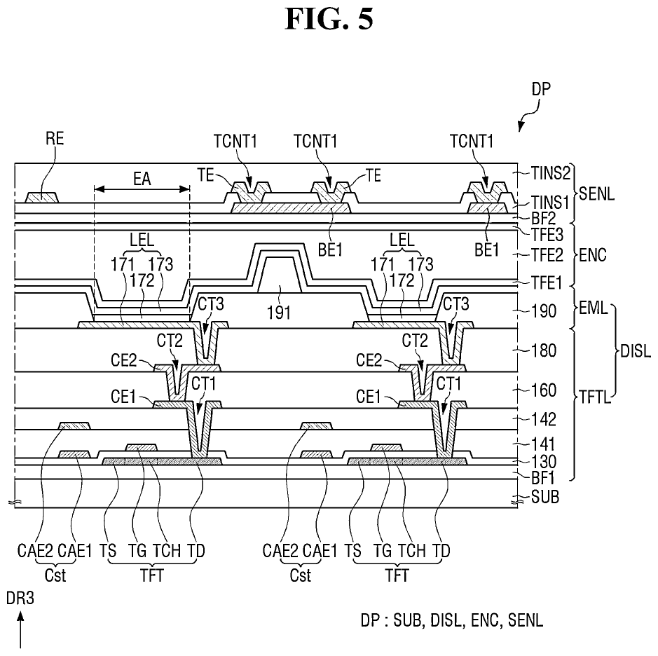

The display layer DISL may be located on a first surface of the substrate SUB. The display layer DISL may be a layer displaying an image. The display layer DISL may include a thin film transistor layer TFTL (see FIG. 5) in which thin film transistors are formed and a light emitting element layer EML (see FIG. 5) in which light emitting elements emitting light are located in emission areas.

The display layer DISL may include scan lines, data lines, power lines, and the like, for allowing the emission areas to emit the light in the display area DA. The display layer DISL may include a scan driving circuit unit outputting scan signals to the scan lines and fan-out lines connecting the data lines and a driving integrated chip (IC) to each other, in the non-display area NDA.

The encapsulation layer ENC may be a layer for encapsulating the light emitting element layer of the display layer DISL in order to prevent or reduce instances of contaminants, oxygen, or moisture from permeating into the light emitting element layer of the display layer DISL. The encapsulation layer ENC may be located on the display layer DISL. The encapsulation layer ENC may be located on an upper surface and side surfaces of the display layer DISL. The encapsulation layer ENC may be arranged to cover the display layer DISL.

The sensor electrode layer SENL may be located on the display layer DISL. The sensor electrode layer SENL may include sensor electrodes. The sensor electrode layer SENL may sense a user's touch using sensor electrodes.

The polarizing film PF may be located on the sensor electrode layer SENL. The polarizing film PF may be located on the display panel DP in order to reduce external light reflection. The polarizing film PF may include a first base member, a linear polarizer, a phase retardation film such as a λ/4 plate (quarter-wave plate), and a second base member. The first base member, the phase retardation film, the linear polarizer, and the second base member of the polarizing film PF may be sequentially stacked on the display panel DP.

The cover window CW may be located on the polarizing film PF. The cover window CW may have a transparent property so that light generated from the display panel DP may be transmitted therethrough. The cover window CW may include a glass or plastic material. According to some embodiments, when the cover window CW includes glass, the cover window CW may include chemically ion-substituted tempered glass. According to some embodiments, when the cover window CW includes plastic, the cover window CW may include a polyimide (PI) film.

The cover window CW may be attached onto the polarizing film PF by the adhesive member ADH. The adhesive member ADH may include any one of a pressure sensitive adhesive (PSA), an optical clear adhesive (OCA), and an optical clear resin (OCR).

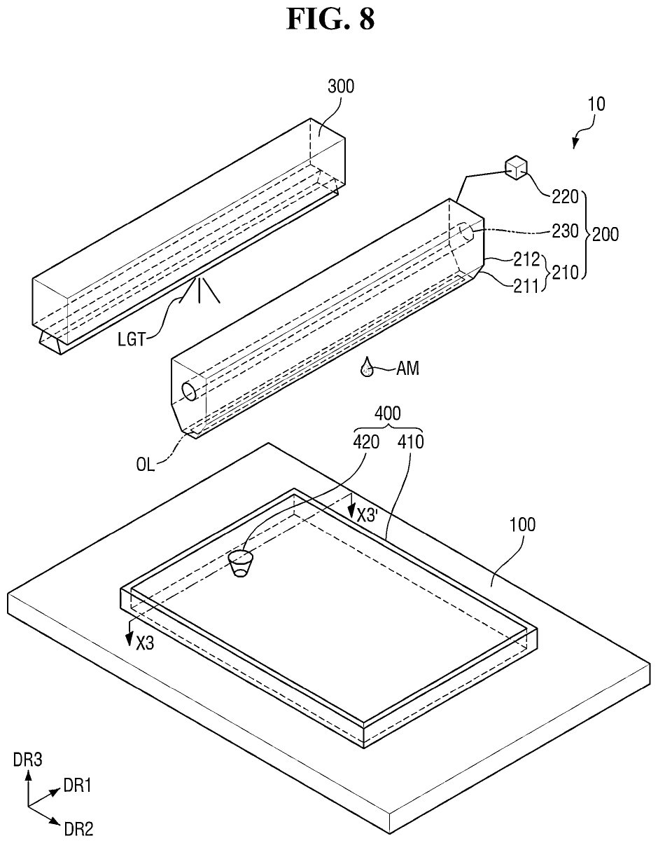

According to some embodiments, when the adhesive member ADH includes the optical clear resin (OCR), the adhesive member ADH may be formed by applying and then hardening a liquid adhesive material AM (see FIG. 8) using an apparatus 10 (see FIG. 8) for manufacturing a display device to be described in more detail below.

The panel lower cover PB may be located on a second surface of the substrate SUB of the display panel DP. The second surface of the substrate SUB may be a surface opposite to the first surface of the substrate SUB. The panel lower cover PB may be attached to the second surface of the substrate SUB of the display panel DP through an adhesive member such as a pressure sensitive adhesive (PSA).

The panel lower cover PB may include at least one of a light blocking member for absorbing light incident from the outside, a buffer member for absorbing impact from the outside, or a heat dissipation member for relatively efficiently dissipating heat of the display panel DP.

The display device DD may further include a through hole TH and an optical device OPD located in the through hole TH.

The through hole TH may be located in the transmissive hole area THA. The through hole TH is a hole capable of transmitting light therethrough, and may be a physical hole penetrating through the panel lower cover PB, the polarizing film PF, and the adhesive member ADH as well as the display panel DP. The cover window CW may be arranged to cover the through hole TH.

The optical device OPD may be spaced apart from the display panel DP, the panel lower cover PB, and the polarizing film PF. The optical device OPD may be an optical sensor sensing light incident through the through hole TH, such as a proximity sensor, an illuminance sensor, and a camera sensor.

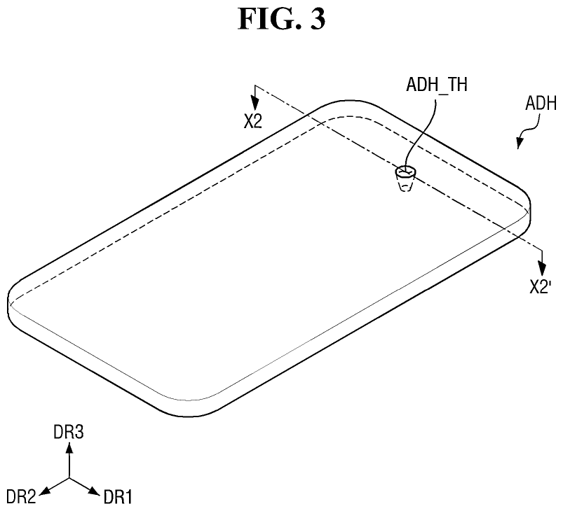

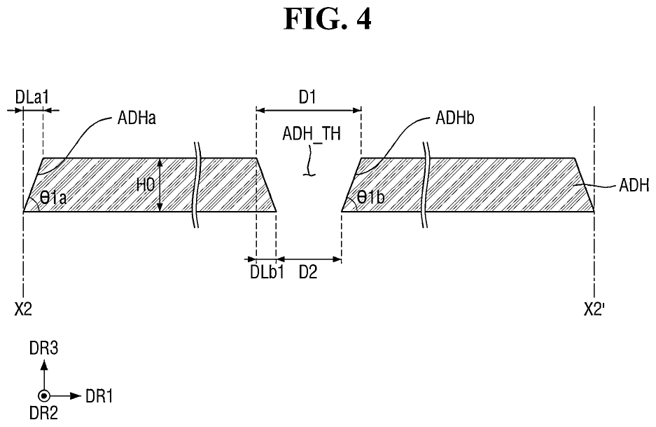

FIG. 3 is a perspective view illustrating an adhesive member according to some embodiments. FIG. 4 is a cross-sectional view taken along line X2-X2′ of FIG. 3.

Referring to FIGS. 3 and 4, a shape of the adhesive member ADH in plan view may correspond to the shape of the display device DD in plan view. For example, the adhesive member ADH may have an approximately rectangular shape of which each corner is rounded on the plane along the first direction DR1 and the second direction DR2, like the display device DD. However, a shape of the adhesive member ADH is not limited thereto, and may be variously changed depending on the shape of the display device DD.

According to some embodiments, a side surface ADHa of the adhesive member ADH may be an inclined surface of a normal-tapered shape. For example, the side surface ADHa of the adhesive member ADH may be an inclined surface inclined in an outward direction of the adhesive member ADH from top to bottom.

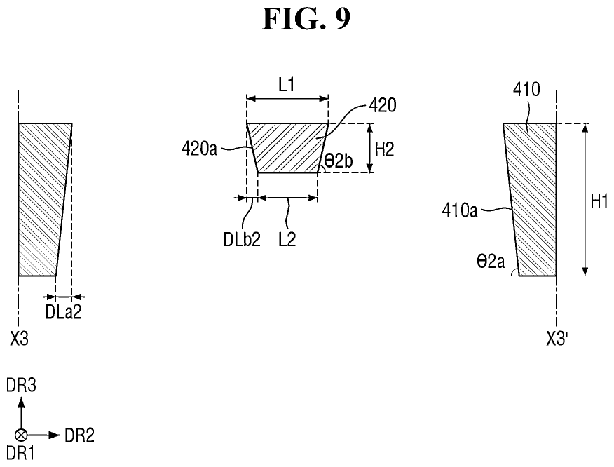

According to some embodiments, a first angle θ1a formed between the side surface ADHa and a lower surface of the adhesive member ADH may be 60° or more and less than 90°. In the display device DD according to some embodiments, a shape of the side surface ADHa of the adhesive member ADH may correspond to a shape of an inner side surface 410a (see FIG. 9) of a first mold 410 (see FIG. 8) of an apparatus 10 (see FIG. 8) for manufacturing a display device to be described later. By forming the side surface ADHa of the adhesive member ADH so that the first angle θ1a is less than 90° using the first mold 410 (see FIG. 8), the first mold 410 (see FIG. 8) may be easily removed during a process of manufacturing the adhesive member ADH. In addition, by forming the first angle θ1a so as to be 60° or more, a difference in adhesive force between upper and lower surfaces of the adhesive member ADH occurring according to a first horizontal length DLa1, which is a horizontal length of the side surface ADHa of the adhesive member ADH, may be minimized.

As an example, the first horizontal length DLa1 may be within 30 μm. In the display device DD according to some embodiments, a magnitude of the first angle θ1a may be changed depending on a height H0 of the adhesive member ADH in order to keep the first horizontal length DLa1 within 30 μm. For example, when the height H0 of the adhesive member ADH is within 50 μm, the first angle θ1a may be 60° or more, when the height H0 of the adhesive member ADH is within 100 μm, the first angle θ1a may be 70° or more, and when the height H0 of the adhesive member ADH is within 200 μm, the first angle θ1a may be 80° or more.

However, the present disclosure is not limited thereto, and according to some embodiments, the side surface ADHa of the adhesive member ADH may be a vertical surface, and the first angle θ1a may be 90°.

The adhesive member ADH may include a first through hole ADH_TH. The first through hole ADH_TH may be a portion of the through hole TH of the display panel DP described with reference to FIG. 2. The first through hole ADH_TH may be a physical hole penetrating through the adhesive member ADH in the third direction DR3.

According to some embodiments, the first through hole ADH_TH may have a reverse-tapered shape. For example, a width D1 of an upper opening of the first through hole ADH_TH may be greater than a width D2 of a lower opening of the first through hole ADH_TH.

According to some embodiments, a side surface ADHb of the first through hole ADH_TH may be a inclined surface of the reverse-tapered shape. For example, the side surface ADHb of the first through hole ADH_TH may be an inclined surface inclined in an inward direction of the first through hole ADH_TH from top to bottom.

According to some embodiments, a second angle θ1b formed between the side surface ADHb of the first through hole ADH_TH and the lower surface of the adhesive member ADH may be 60° or more and less than 90°. In the display device DD according to some embodiments, a shape of the side surface ADHb of the first through hole ADH_TH may correspond to a shape of a side surface 420a (see FIG. 9) of a second mold 420 (see FIG. 8) of an apparatus 10 (see FIG. 8) for manufacturing a display device to be described later. By forming the side surface ADHb of the first through hole ADH_TH so that the second angle θ1b is less than 90° using the second mold 420 (see FIG. 8), the second mold 420 (see FIG. 8) may be easily removed during the process of manufacturing the adhesive member ADH. In addition, by forming the second angle θ1b so as to be 60° or more, a difference in adhesive force between the upper and lower surfaces of the adhesive member ADH occurring according to a second horizontal length DLb1, which is a horizontal length of the side surface ADHb of the first through hole ADH_TH, may be minimized.

As an example, the second horizontal length DLb1 may be within 30 μm. In the display device DD according to some embodiments, a magnitude of the second angle θ1b may be changed depending on the height H0 of the adhesive member ADH in order to keep the second horizontal length DLb1 within 30 μm. For example, when the height H0 of the adhesive member ADH is within 50 μm, the second angle θ1b may be 60° or more, when the height H0 of the adhesive member ADH is within 100 μm, the second angle θ1b may be 70° or more, and when the height H0 of the adhesive member ADH is within 200 μm, the second angle θ1b may be 80° or more.

However, the present disclosure is not limited thereto, and according to some embodiments, the side surface ADHb of the first through hole ADH_TH may be a vertical surface, and the second angle θ1b may be 90°.

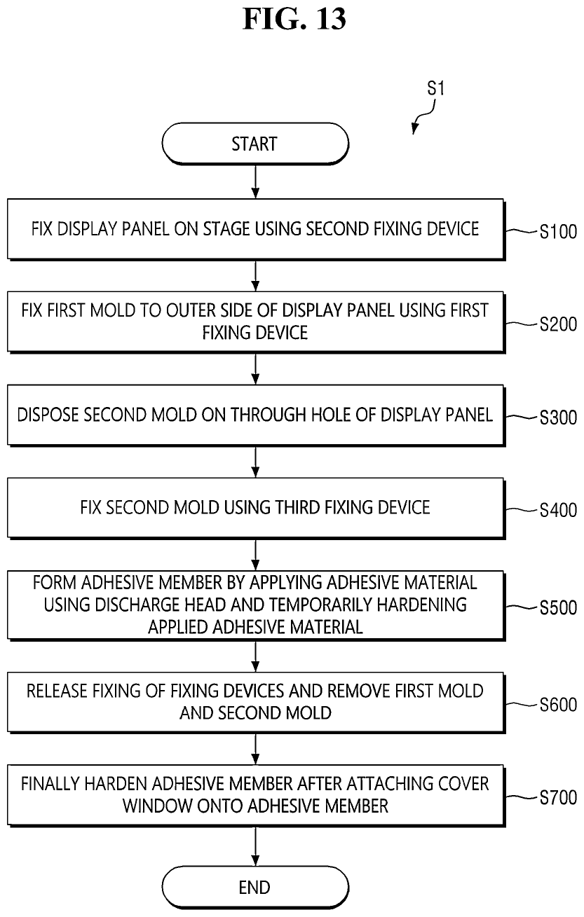

An apparatus 10 for manufacturing a display device and a method S1 for manufacturing a display device for forming the adhesive member ADH will be described later with reference to FIGS. 8 and 13 and the like.

FIG. 5 is a cross-sectional view illustrating an example of a display panel according to some embodiments.

Referring to FIG. 5, according to some embodiments, the display panel DP may be an organic light emitting display panel including light emitting elements LEL each including an organic light emitting layer 172. The display panel DP may include a substrate SUB, a display layer DISL, an encapsulation layer ENC, and a sensor electrode layer SENL. The display layer DISL may include a thin film transistor layer TFTL including a plurality of thin film transistors and a light emitting element layer EML including a plurality of light emitting elements.

The substrate SUB may include a transparent material. For example, the substrate SUB may include a transparent insulating material such as glass or quartz. The substrate SUB may be a rigid substrate. However, the substrate SUB is not limited thereto, and may include plastic such as polyimide, and may have flexible characteristics so as to be curved, bent, folded, or rolled.

The display layer DISL may include the thin film transistor layer TFTL including the plurality of thin film transistors and the light emitting element layer EML including the plurality of light emitting elements.

The thin film transistor layer TFTL may include a first buffer film BF1, thin film transistors TFT, a gate insulating film 130, a first interlayer insulating film 141, capacitors Cst, a second interlayer insulating film 142, a first data metal layer, a first organic film 160, a second data metal layer, and a second organic film 180.

The first buffer film BF1 may be located on the substrate SUB. The first buffer film BF1 may be made of an inorganic material such as a silicon nitride layer, a silicon oxynitride layer, a silicon oxide layer, a titanium oxide layer, and an aluminum oxide layer. Alternatively, the first buffer film BF1 may be formed as multiple films in which a plurality of layers of a silicon nitride layer, a silicon oxynitride layer, a silicon oxide layer, a titanium oxide layer, and an aluminum oxide layer are alternately stacked.

An active layer including a channel region TCH, a source region TS, and a drain region TD of the thin film transistor TFT may be located on the first buffer film BF1. The active layer may be made of polycrystalline silicon, single crystal silicon, low-temperature polycrystalline silicon, amorphous silicon, or an oxide semiconductor material. When the active layer includes the polycrystalline silicon or the oxide semiconductor material, the source region TS and drain region TD in the active layer may be conductive regions doped with ions or impurities to have conductivity.

The gate insulating film 130 may be located on the active layers of the thin film transistors TFT. The gate insulating film 130 may be formed as an inorganic film such as a silicon nitride layer, a silicon oxynitride layer, a silicon oxide layer, a titanium oxide layer, or an aluminum oxide layer.

A first gate metal layer including gate electrodes TG of the thin film transistors TFT, first capacitor electrodes CAE1 of the capacitors Cst, and scan lines may be located on the gate insulating film 130. The gate electrode TG of the thin film transistor TFT may overlap the channel region TCH in the third direction (Z-axis direction). The first gate metal layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first interlayer insulating film 141 may be located on the first gate metal layer. The first interlayer insulating film 141 may be formed as an inorganic film such as a silicon nitride layer, a silicon oxynitride layer, a silicon oxide layer, a titanium oxide layer, or an aluminum oxide layer. The first interlayer insulating film 141 may include a plurality of inorganic films.

A second gate metal layer including second capacitor electrodes CAE2 of the capacitors Cst may be located on the first interlayer insulating film 141. The second capacitor electrode CAE2 may overlap the first capacitor electrode CAE1 in the third direction (Z-axis direction). Therefore, the capacitor Cst may be formed by the first capacitor electrode CAE1, the second capacitor electrode CAE2, and an inorganic insulating dielectric film located between the first capacitor electrode CAE1 and the second capacitor electrode CAE2 and serving as a dielectric film. The second gate metal layer may be formed as a single layer or multiple layers made of any one of molybdenum (Mo), aluminum (AI), chromium (Cr), gold (Au), titanium (Ti), nickel (Ni), neodymium (Nd), and copper (Cu), or alloys thereof.

The second interlayer insulating film 142 may be located on the second gate metal layer. The second interlayer insulating film 142 may be formed as an inorganic film such as a silicon nitride layer, a silicon oxynitride layer, a silicon oxide layer, a titanium oxide layer, or an aluminum oxide layer. The second interlayer insulating film 142 may include a plurality of inorganic films.

The first data metal layer including first connection electrodes CE1 and data lines may be located on the second interlayer insulating film 142. The first connection electrode CE1 may be connected to the drain region TD through a first connection contact hole CT1 penetrating through the gate insulating film 130, the first interlayer insulating film 141, and the second interlayer insulating film 142. The first data metal layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first organic film 160 for planarizing a step due to the thin film transistors TFT may be located on the first connection electrodes CE1. The first organic film 160 may be formed as an organic film made of an acrylic resin, an epoxy resin, a phenolic resin, a polyamide resin, a polyimide resin, or the like.

The second data metal layer including second connection electrodes CE2 may be located on the first organic film 160. The second data metal layer may be connected to the first connection electrode CE1 through a second contact hole CT2 penetrating through the first organic film 160. The second data metal layer may be formed as a single layer or multiple layers made of any one of molybdenum (Mo), aluminum (AI), chromium (Cr), gold (Au), titanium (Ti), nickel (Ni), neodymium (Nd), and copper (Cu), or alloys thereof.

The second organic film 180 may be located on the second connection electrodes CE2. The second organic film 180 may be formed as an organic film made of an acrylic resin, an epoxy resin, a phenolic resin, a polyamide resin, a polyimide resin, or the like.

Meanwhile, the second data metal layer including the second connection electrodes CE2 and the second organic film 180 may be omitted.

The light emitting element layer EML is located on the thin film transistor layer TFTL. The light emitting element layer EML may include light emitting elements LEL and a pixel defining film 190.

Each of the light emitting elements LEL may include a pixel electrode 171, a light emitting layer 172, and a common electrode 173. Each of emission areas EA refers to an area in which the pixel electrode 171, the light emitting layer 172, and the common electrode 173 are sequentially stacked and holes from the pixel electrode 171 and electrons from the common electrode 173 are combined with each other in the light emitting layer 172 to emit light. In this case, the pixel electrode 171 may be an anode electrode, and the common electrode 173 may be a cathode electrode.

A pixel electrode layer including the pixel electrodes 171 may be formed on the second organic film 180. The pixel electrode 171 may be connected to the second connection electrode CE2 through a third connection hole CT3 penetrating through the second organic film 180. The pixel electrode layer may be formed as a single layer or multiple layers made of any one of molybdenum (Mo), aluminum (AI), chromium (Cr), gold (Au), titanium (Ti), nickel (Ni), neodymium (Nd), and copper (Cu), or alloys thereof.

In a top emission structure in which light is emitted toward the common electrode 173 based on the light emitting layer 172, the pixel electrode 171 may be formed as a single layer made of molybdenum (Mo), titanium (Ti), copper (Cu), or aluminum (Al) or be formed as a stacked structure (Ti/Al/Ti) of aluminum and titanium, a stacked structure (ITO/AI/ITO) of aluminum and indium tin oxide (ITO), an APC alloy, and a stacked structure (ITO/APC/ITO) of an APC alloy and ITO in order to increase reflectivity. The APC alloy is an alloy of silver (Ag), palladium (Pd), and copper (Cu).

The pixel defining film 190 serves to define the emission areas EA of the pixels. To this end, the pixel defining film 190 may be formed to expose partial areas of the pixel electrodes 171 on the second organic film 180. The pixel defining film 190 may cover edges of the pixel electrodes 171. The pixel defining film 190 may be located within the third contact holes CT3. That is, the third contact holes CT3 may be filled with the pixel defining film 190. The pixel defining film 190 may be formed as an organic film made of an acrylic resin, an epoxy resin, a phenolic resin, a polyamide resin, a polyimide resin, or the like.

A spacer 191 may be located on the pixel defining film 190. The spacer 191 may serve to support a mask during a process of manufacturing the light emitting layer 172. The spacer 191 may be formed as an organic film made of an acrylic resin, an epoxy resin, a phenolic resin, a polyamide resin, a polyimide resin, or the like.

The light emitting layer 172 is formed on the pixel electrode 171. The light emitting layer 172 may include an organic material to emit light of a color (e.g., a set or predetermined color). For example, the light emitting layer 172 may include a hole transporting layer, an organic material layer, and an electron transporting layer. The organic material layer may include a host and a dopant. The organic material layer may include a material emitting light (e.g., set or predetermined light), and may be formed using a phosphorescent material or a fluorescent material.

The common electrode 173 is formed on the light emitting layer 172. The common electrode 173 may be formed to cover the light emitting layer 172. The common electrode 173 may be a common layer formed in common in the emission areas EA. A capping layer may be formed on the common electrode 173.

In the top emission structure, the common electrode 173 may be made of a transparent conductive material (TCO) such as ITO or indium zinc oxide (IZO) capable of transmitting light therethrough or a semi-transmissive conductive material such as magnesium (Mg), silver (Ag), or an alloy of magnesium (Mg) and silver (Ag). When the common electrode 173 is made of the semi-transmissive conductive material, emission efficiency may be increased by a micro cavity.

The encapsulation layer ENC may be located on the light emitting element layer EML. The encapsulation layer ENC may include at least one inorganic film TFE1 or TFE3 in order to prevent or reduce instances of contaminants, oxygen, and/or moisture permeating into the light emitting element layer EML. In addition, the encapsulation layer ENC may include at least one organic film TFE2 in order to protect the light emitting element layer EML from foreign substances such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be located on the common electrode 173, the encapsulation organic film TFE2 may be located on the first encapsulation inorganic film TFE1, and the second encapsulation inorganic film TFE3 may be located on the encapsulation organic film TFE2. The first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film made of an acrylic resin, an epoxy resin, a phenolic resin, a polyamide resin, a polyimide resin, or the like.

The sensor electrode layer SENL may be located on the encapsulation layer ENC. The sensor electrode layer SENL may include a second buffer film BF2, first connection parts BE1, a first sensor insulating film TINS1, sensor electrodes TE and RE, and a second sensor insulating film TINS2.

The second buffer film BF2 may be located on the encapsulation layer ENC. The second buffer film BF2 may include at least one inorganic film. For example, the second buffer film BF2 may be formed as multiple films in which one or more inorganic films of a silicon nitride layer, a silicon oxynitride layer, a silicon oxide layer, a titanium oxide layer, and an aluminum oxide layer are alternately stacked. The second buffer film BF2 may be omitted.

The first connection parts BE1 may be located on the second buffer film BF2. The first connection parts BE1 may be formed as a single layer made of molybdenum (Mo), titanium (Ti), copper (Cu), or aluminum (Al) or be formed as a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO.

The first sensor insulating film TINS1 may be located on the first connection parts BE1. The first sensor insulating film TINS1 may be formed as an inorganic film such as a silicon nitride layer, a silicon oxynitride layer, a silicon oxide layer, a titanium oxide layer, or an aluminum oxide layer.

The sensor electrodes, that is, driving electrodes TE and sensing electrodes RE, may be located on the first sensor insulating film TNIS1. In addition, dummy patterns may be located on the first sensor insulating film TNIS1. The driving electrodes TE, the sensing electrodes RE, and the dummy patterns do not overlap the emission areas EA. Each of the driving electrodes TE, the sensing electrodes RE, and the dummy patterns may be formed as a single layer made of molybdenum (Mo), titanium (Ti), copper (Cu), or aluminum (Al) or be formed as a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO.

The second sensor insulating film TINS2 may be located on the driving electrodes TE, the sensing electrodes RE, and the dummy patterns. The second sensor insulating film TINS2 may include at least one of an inorganic film or an organic film. The inorganic film may be a silicon nitride layer, a silicon oxynitride layer, a silicon oxide layer, a titanium oxide layer, or an aluminum oxide layer. The organic film may be made of an acrylic resin, an epoxy resin, a phenolic resin, a polyamide resin, or a polyimide resin.

Hereinafter, further details of a display device according to some embodiments of the present disclosure will be described. In the following embodiments, the same components as those of the above-described embodiments will be denoted by the same reference numerals, and some repetitive description of some of the same or similar components may be omitted or simplified and contents different from those described above will be mainly described.

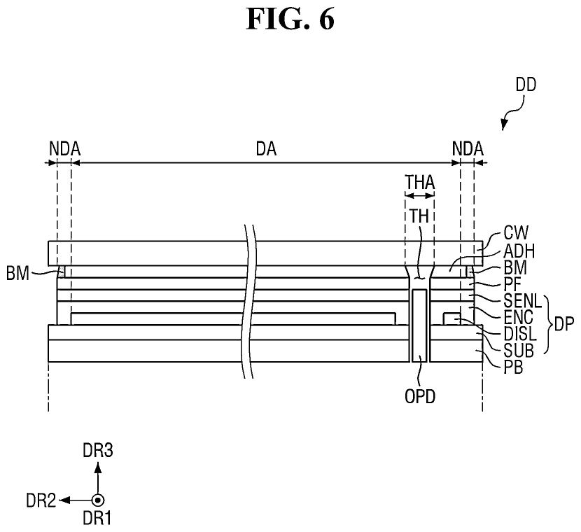

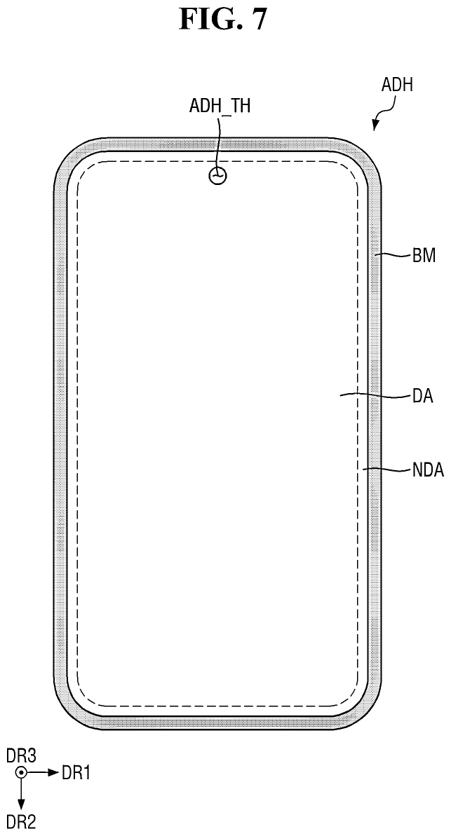

FIG. 6 is a cross-sectional view illustrating a display device according to some embodiments. FIG. 7 is a plan view illustrating an adhesive member according to some embodiments.

Referring to FIGS. 6 and 7, a display device DD according to the present embodiments is different from the display device DD according to an embodiments described with reference to FIG. 1 and the like in that the adhesive member ADH includes a light blocking member BM.

For example, the adhesive member ADH may include the light blocking member BM. The light blocking member BM may be arranged along an edge of the adhesive member ADH. The light blocking member BM may be located in the non-display area NDA. The light blocking member BM may be arranged to surround the display area DA.

According to some embodiments, a side surface of the light blocking member BM may be an inclined surface. In this case, a shape of the side surface of the light blocking member BM may be the same as the shape of the side surface ADHa of the adhesive member ADH described above with reference to FIGS. 3 and 4 and the like.

The light blocking member BM may prevent or reduce instances of light leaking to the outside of the display device DD. The light blocking member BM may include a light blocking material. For example, the light blocking member BM may include at least one of an organic black pigment such as black carbon particles and/or light blocking metal particles.

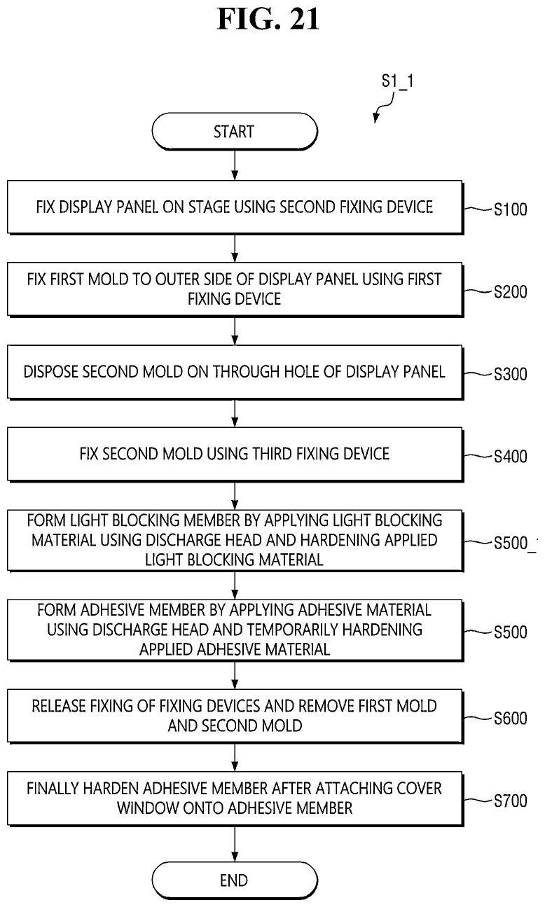

In the display device DD according to some embodiments, the light blocking member BM may be formed along with a process of forming the adhesive member ADH according to a method S1_1 (see FIG. 21) for manufacturing a display device to be described later. Accordingly, an additional process for forming a separate light blocking member BM on the cover window CW or forming a separate light blocking member BM along a circumference of the display device DD may not be performed.

A method S1_1 (see FIG. 21) for manufacturing a display device for forming the light blocking member BM will be described later with reference to FIG. 21 and the like.

FIG. 8 is a perspective view illustrating an apparatus for manufacturing a display device according to some embodiments. FIG. 9 is a cross-sectional view taken along line X3-X3′ of FIG. 8.

Referring to FIGS. 8 and 9, an apparatus 10 for manufacturing a display device according to some embodiments may be a manufacturing apparatus for forming the above-described adhesive member ADH. For example, the apparatus 10 for manufacturing a display device may be a manufacturing apparatus that discharges an adhesive material AM and hardens the adhesive material AM to form the adhesive member ADH.

The apparatus 10 for manufacturing a display device may include a stage 100, a discharge head 200, a light irradiation part 300, and a mold 400.

The stage 100 may provide a space in which a target substrate is seated. Here, the target substrate may be the display panel DP described with reference to FIG. 1 and the like, but is not limited thereto. The stage 100 may have a flat panel shape. A shape of the stage 100 in plan view may be similar to a shape of the target substrate in plan view. For example, the shape of the stage 100 in plan view may be an approximately rectangular shape, but is not limited thereto.

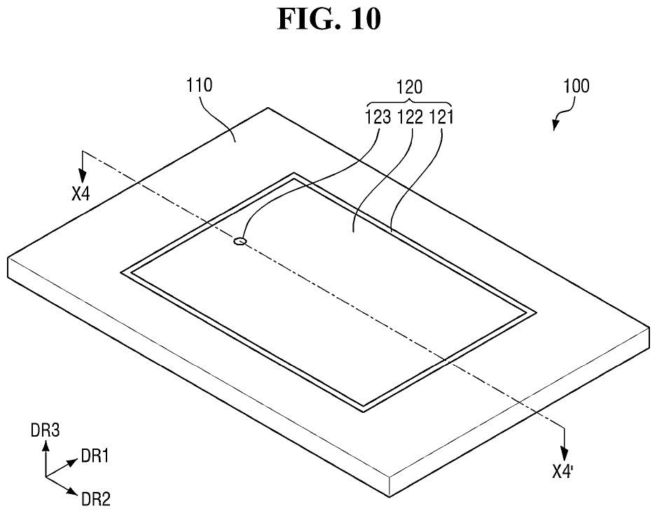

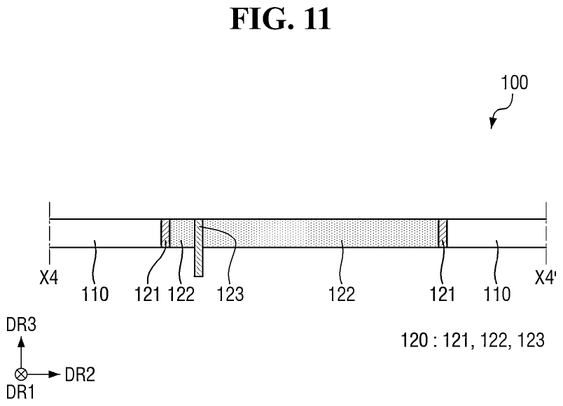

A detailed structure of the stage 100 will be described later with reference to FIGS. 10 and 11.

The discharge head 200 may discharge the adhesive material AM. The discharge head 200 may apply the adhesive material AM onto one side surface of the target substrate fixed to one side of the stage 100 in the third direction DR3.

The discharge head 200 may be positioned on one side of the stage 100 in the third direction DR3. For example, the discharge head 200 may be positioned above the stage 100 in a direction opposite to a direction in which gravity acts. In the present specification, the direction in which the gravity acts may refer to the other side of the third direction DR3, and the direction opposite to the direction in which the gravity acts may refer to one side of the third direction DR3.

The discharge head 200 may include a main body part 210, a discharge driving part 220, and a stirring part 230.

The main body part 210 may include an internal space accommodating the adhesive material AM. The main body part 210 may have a shape in which it extends in the first direction DR1. The main body part 210 may include an accommodating part 212 and a discharge part 211.

The accommodating part 212 may accommodate the adhesive material AM. For example, the adhesive material AM may be accommodated in an internal space of the accommodating part 212.

The discharge part 211 may be positioned between the accommodating part 212 and the stage 100. For example, the discharge part 211 may be located on the other side of the accommodating part 212 in the third direction DR3. The discharge part 211 may be spatially connected to the accommodating part 212.

The discharge part 211 may include a discharge port OL opened on the other side in the third direction DR3. The discharge port OL may have a shape in which it extends in the first direction DR1. The discharge port OL may be arranged to face one surface of the stage 100 in the third direction DR3.

The discharge driving part 220 may be connected to the main body part 210. The discharge driving part 220 may transfer a driving force for discharging the adhesive material AM accommodated in the main body part 210 to the outside to the main body part 210. For example, the discharge driving part 220 may include a syringe or a pump.

The discharge driving part 220 may provide a discharge driving force for pushing the adhesive material AM of the discharge part 211 to the outside. That is, the adhesive material AM may be discharged to the outside by the discharge driving force provided from the discharge driving part 220.

The discharge driving part 220 may assist in discharging the adhesive material AM of the discharge part 211 to the outside. The adhesive material AM of the discharge part 211 may move toward the target substrate due to an attractive force with the target substrate. In this case, when the adhesive material AM located in the discharge part 211 moves toward the target substrate, the discharge driving part 220 may move the adhesive material AM located in the accommodating part 212 toward the discharge part 211.

The stirring part 230 may be located inside the main body part 210. According to some embodiments, the stirring part 230 may include a roller extending in the first direction DR1. The stirring part 230 may adjust a viscosity of the adhesive material AM through rotation of the roller. For example, the roller included in the stirring part 230 may maintain the viscosity of the adhesive material AM while rotating a certain number of times per unit time. In addition, in order to maintain the viscosity of the adhesive material AM, the number of rotations per unit time of the roller may be increased when the viscosity of the adhesive material AM increases, and conversely, the number of rotations per unit time of the roller may be decreased when the viscosity of the adhesive material AM decreases.

The light irradiation part 300 may irradiate the adhesive material AM applied onto the target substrate with light LGT to temporarily harden the adhesive material AM. For example, the light irradiation part 300 may irradiate ultraviolet light LGT, but is not limited thereto. The light irradiation part 300 may irradiate the light LGT toward the other side of the third direction DR3. For example, the light irradiation part 300 may irradiate the light LGT toward the stage 100.

The light irradiation part 300 may be located on one side of the discharge head 200. For example, the light irradiation part 300 may be located on one side of the discharge head 200 in the second direction DR2. According to some embodiments, the light irradiation part 300 may be located in a direction opposite to a moving direction of the discharge head 200.

The light irradiation part 300 may be positioned on one side of the stage 100 in the third direction DR3, like the discharge head 200. For example, the light irradiation part 300 may be positioned above the stage 100 in the direction opposite to the direction in which the gravity acts.

The light irradiation part 300 may radiate light LGT toward one side in the third direction DR3. The light LGT irradiated by the light irradiation part (or light irradiation component or light irradiator) 300 may be ultraviolet rays. The light LGT irradiated by the light irradiation part 300 may temporarily harden the adhesive material AM applied onto the target substrate.

The light irradiation part 300 may have a shape in which it extends in the first direction DR1. The light LGT irradiated by the light irradiation part 300 may be irradiated in the form of linear light extending in the first direction DR1. However, the present disclosure is not limited thereto, and the light LGT irradiated by the light irradiation part 300 may also be irradiated in the form of surface light extending in the first direction DR1, but having a width (e.g., a set or predetermined width).

The mold 400 may be located on stage 100. The mold 400 may provide a space in which the target substrate and the adhesive material AM may be accommodated. When the target substrate is seated on the stage 100, the mold 400 may surround the target substrate.

A shape of the mold 400 may be similar to the shape of the target substrate. For example, a shape of the mold 400 in plan view may be an approximately rectangular shape, but is not limited thereto. A size and a shape of an internal space defined by inner sidewalls of the mold 400 may be the same as a size and a shape of the target substrate.

According to some embodiments, the mold 400 may include a silicone-based or fluorine-based material. For example, when the mold 400 includes the silicone-based material, the mold 400 may include polydimethylsiloxane (PDMS). When the mold 400 includes the fluorine-based material, the mold 400 may include polytetrafluoroethylene (PTFE).

According to some embodiments, the mold 400 may include at least one of metal, glass, or plastic. In this case, during a process of forming the adhesive member ADH, a mold release agent may be applied to a surface on which the adhesive material AM and the mold 400 are in contact with each other.

The mold 400 may include a first mold 410 and a second mold 420.

The first mold 410 may be in the form of a partition wall configured to surround an outer side of the target substrate. A height H1 of the first mold 410 may be greater than a height of the target substrate. For example, the height H1 of the first mold 410 may be greater than or equal to the sum of heights of the target substrate and the adhesive member ADH located on the target substrate. As an example, the height H1 of the first mold 410 may be 10 micrometers (μm) to 500 μm (or approximately 10 μm to 500 μm). Preferably, the height H1 of the first mold 410 may be 100 μm to 500 μm (or approximately 100 μm to 500 μm).

When the adhesive member ADH is formed using an apparatus 10 for manufacturing a display device according to the related art that does not include the first mold 410, as a thickness of the applied adhesive material AM increases, a difference in thickness between a central portion and an outer side portion of the adhesive member may increase due to surface tension and an intermolecular attractive force. When an amount (e.g., a set or predetermined amount) or more of adhesive material AM is applied to form a sufficient thickness on the outer side portion, the adhesive material AM may overflow to the outside of the target substrate.

The apparatus 10 for manufacturing a display device according to some embodiments may prevent or reduce instances of the adhesive material AM overflowing to the outside of the target substrate in the process of forming the adhesive member ADH by including the first mold 410. Accordingly, the adhesive material AM may be applied in a sufficient amount to the outside of the target substrate. Accordingly, the difference in thickness between the central portion and the outer side portion of the adhesive member ADH may be minimized.

According to some embodiments, as illustrated in FIG. 9, an inner side surface 410a of the first mold 410 may be an inclined surface of a reverse-tapered shape. For example, the inner side surface 410a of the first mold 410 may be an inclined surface inclined in an outward direction of the first mold 410 from the top to the bottom.

According to some embodiments, a third angle θ2a, which is an acute angle formed between the inner side surface 410a of the first mold 410 and a lower surface of the first mold 410, may be to 60° or more and less than 90°. In the apparatus 10 for manufacturing a display device according to some embodiments, by forming the third angle θ2a so as to be less than 90°, the first mold 410 may be easily removed during the process of manufacturing the adhesive member ADH. In addition, by forming the third angle θ2a so as to be 60° or more, a difference in adhesive force between the upper and lower surfaces of the adhesive member ADH occurring according to a third horizontal length DLa2, which is a horizontal length of the inner side surface 410a of the first mold 410, may be minimized.

The second mold 420 may be an island-type mold arranged to be spaced apart from the first mold 410. The second mold 420 may be located in an internal space partitioned by the first mold 410. According to some embodiments, when the target substrate includes a through hole TH like the display device DD described above, the second mold 420 may be located on the through hole TH of the target substrate.

According to some embodiments, a height H2 of the second mold 420 may be smaller than the height H1 of the first mold 410. According to some embodiments, the second mold 420 is seated on the target substrate, and thus, the height H1 of the first mold 410 may be the same as the sum of the height H2 of the second mold 420 and the height of the target substrate. In this case, an upper surface of the second mold 420 and an upper surface of the first mold 410 may be positioned at places spaced apart from an upper surface of the stage 100 by the same height. According to some embodiments, the height H2 of the second mold 420 may be substantially the same as the height H0 of the adhesive member ADH described with reference to FIG. 4.

According to some embodiments, as illustrated in FIG. 9, the second mold 420 may have a reverse-tapered shape. For example, a length L1 of the upper surface of the second mold 420 may be greater than a length L2 of a lower surface of the second mold 420.

According to some embodiments, a side surface 420a of the second mold 420 may be an inclined surface of the reverse-tapered shape. For example, the side surface 420a of the second mold 420 may be an inclined surface inclined in an inward direction of the second mold 420 from the top to the bottom.

According to some embodiments, a fourth angle θ2b, which is an acute angle formed between the side surface 420a of the second mold 420 and the lower surface of the second mold 420, may be to 60° or more and less than 90°. In the apparatus 10 for manufacturing a display device according to some embodiments, by forming the fourth angle θ2b so as to be less than 90°, the second mold 420 may be easily removed during the process of manufacturing the adhesive member ADH. In addition, by forming the fourth angle θ2b so as to be 60° or more, a difference in adhesive force between the upper and lower surfaces of the adhesive member ADH occurring according to a fourth horizontal length DLb2, which is a horizontal length of the side surface 420a of the second mold 420, may be minimized.

As an example, the fourth horizontal length DLb2 may be the same as the second horizontal length DLb1 described with reference to FIG. 4. For example, the fourth horizontal length DLb2 may be within 30 μm. In the apparatus 10 for manufacturing a display device according to some embodiments, a magnitude of the fourth angle θ2b may be changed depending on the height H2 of the second mold 420 in order to keep the fourth horizontal length DLb2 within 30 μm. For example, when the height H2 of the second mold 420 is within 50 μm, the fourth angle θ2b may be 60° or more, when the height H2 of the second mold 420 is within 100 μm, the fourth angle 02b may be 70° or more, and when the height H2 of the second mold 420 is within 200μm, the fourth angle θ2b may be 80° or more.

However, embodiments according to the present disclosure are not limited thereto, and according to some embodiments, the side surface of the second mold 420 may be a vertical surface, and the fourth angle θ2b may be 90°.

The apparatus 10 for manufacturing a display device according to some embodiments may prevent or reduce instances of the adhesive material AM permeating into the through hole TH of the display panel DP by including the second mold 420.

According to some embodiments, the apparatus 10 for manufacturing a display device may further include a separate transfer device for seating the mold 400 on the stage 100 or removing the mold 400 from the stage 100. For example, the transfer device may mount the mold 400 on a fixing part such as an arm to seat the mold 400 on the stage 100 or remove the mold 400 from the stage 100.

The mold 400 seated on the stage 100 may be fixed by a fixing device 120 (see FIG. 10) in the process of forming the adhesive member ADH. Hereinafter, the stage 100 including the fixing device 120 will be described.

FIG. 10 is a perspective view illustrating a stage according to some embodiments. FIG. 11 is a cross-sectional view taken along line X4-X4′ in FIG. 9.

Referring to FIGS. 10 and 11, the apparatus 10 for manufacturing a display device according to some embodiments may include a fixing device 120. It has been illustrated in FIGS. 10 and 11 that the fixing device 120 is built into the stage 100, but the present disclosure is not limited thereto. Hereinafter, for convenience of explanation, a case where the fixing device 120 is included in the stage 100 will be described by way of example.

The stage 100 may include a body part 110 and the fixing device 120.

The body part 110 may configure an appearance of the stage 100. The body part 110 may be arranged to surround the fixing device 120.

The fixing device 120 may be surrounded by the body part 110. The fixing device 120 may function to fix the mold 400 and the target substrate located on the stage 100.

The fixing device 120 may include a first fixing device 121, a second fixing device 122, and a third fixing device 123.

The first fixing device 121 may be a device for fixing the first mold 410. The second fixing device 122 may be a device for fixing the target substrate. The third fixing device 123 may be a device for fixing the second mold 420.

The first fixing device 121 may surround the second fixing device 122 and the third fixing device 123. A shape of the first fixing device 121 in plan view may be similar to a shape of the first mold 410 in plan view. The first fixing device 121 may overlap the first mold 410 in the third direction DR3.

The second fixing device 122 may surround the third fixing device 123. The second fixing device 122 may be surrounded by the first fixing device 121. A shape of the second fixing device 122 in plan view may be similar to a shape, in plan view, of the internal space partitioned by the first mold 410. The second fixing device 122 may overlap the internal space partitioned by the first mold 410 in the third direction DR3.

The third fixing device 123 may be surrounded by the first fixing device 121 and the second fixing device 122. A shape of the third fixing device 123 in plan view may be similar to a shape of the second mold 420 in plan view. The third fixing device 123 may overlap the second mold 420 in the third direction DR3.

According to some embodiments, the first to third fixing devices 121, 122, and 123 may include electrostatic chucks. For example, power may be applied to the first to third fixing devices 121, 122, and 123. The first to third fixing devices 121, 122, and 123 may fix the mold 400 and the target substrate by generating electrostatic forces using the applied power.

According to some embodiments, the first to third fixing devices 121, 122, and 123 may include vacuum suction chucks providing a negative pressure. For example, the first to third fixing devices 121, 122, and 123 may fix the mold 400 and the target substrate by generating suction forces through the negative pressure. According to some embodiments, when the first to third fixing devices 121, 122, and 123 include the vacuum suction chucks, the first to third fixing devices 121, 122, and 123 have a plurality of suction holes.

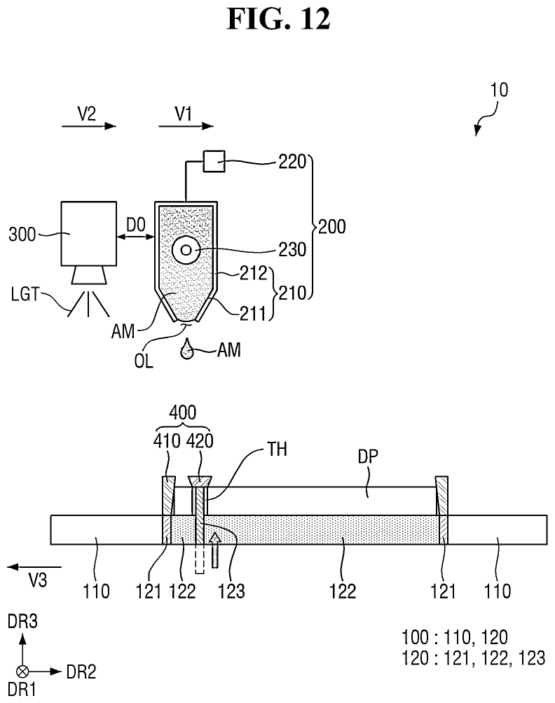

According to some embodiments, in the apparatus 10 for manufacturing a display device according to some embodiments, the third fixing device 123 may further include a separate driving part. For example, the third fixing device 123 may move along the third direction DR3 by the driving part. The third fixing device 123 may move to a position higher than the upper surface of the stage 100. A moving method of the third fixing device 123 will be described below with reference to FIG. 12 along with an operating state of the apparatus 10 for manufacturing a display device.

FIG. 12 is a cross-sectional view illustrating an operating state of the apparatus for manufacturing a display device according to some embodiments.

Referring to FIG. 12 in addition to FIGS. 8 and 9, in the process of forming the adhesive member ADH, the mold 400 and the display panel DP, which is the target substrate, may be fixed on the stage 100 by the fixing device 120. For example, the first mold 410 may be arranged and fixed on the first fixing device 121. The display panel DP may be arranged and fixed on the second fixing device 122. The second mold 420 may be arranged and fixed on the third fixing device 123.

According to some embodiments, when the display panel DP, which is the target substrate, includes the through hole TH like the display device DD described above, the second mold 420 may be located on the through hole TH of the target substrate. In this case, the length L2 of the lower surface of the second mold 420 may be greater than a size of the through hole TH of the target substrate. Accordingly, even though the second mold 420 is located on the through hole TH of the target substrate, the second mold 420 may be prevented from falling into the through hole TH.

The third fixing device 123 may move toward the second mold 420 in the third direction DR3 by the driving part. The third fixing device 123 may pass through the through hole TH and be located adjacent to the second mold 420.

It has been illustrated in FIG. 12 that the first to third fixing devices 121, 122, and 123 are in direct contact with the first mold 410, the display panel DP, and the second mold 420, respectively, but the present disclosure is not limited thereto. The first to third fixing devices 121, 122, and 123 may also fix the first mold 410, the display panel DP, and the second mold 420, respectively, in a state in which they are not in contact with the first mold 410, the display panel DP, and the second mold 420, respectively.

According to some embodiments, the discharge head 200 and the light irradiation part 300 may move to one side in the second direction DR2 at a first moving speed V1 and a second moving speed V2, respectively, on the stage 100. According to some embodiments, the stage 100 may move to the other side in the second direction DR2 at a third moving speed V3 below the discharge head 200 and the light irradiation part 300. According to some embodiments, the discharge head 200 and the light irradiation part 300 may move together to one side of the second direction DR2, and the stage 100 may move to the other side of the second direction DR2. Hereinafter, a case where the discharge head 200 and the light irradiation part 300 move in a state in which the stage 100 is stationary will be described by way of example.

The discharge head 200 may discharge the adhesive material AM while moving in the second direction DR2. Since the discharge head 200 is positioned on the stage 100 and the discharge port OL of the discharge head 200 is opened toward the stage 100, the adhesive material AM discharged from the discharge head 200 may be applied onto the target substrate fixed on one surface of the stage 100.

The discharge port OL may have a shape in which it extends in the first direction DR1. Accordingly, when the discharge head 200 applies the adhesive material AM while moving in the second direction DR2, the adhesive material AM may be applied to an area (e.g., a set or predetermined area) defined by the first direction DR1 and the second direction DR2 of the target substrate. For example, when the discharge port OL has a first length in the first direction DR1, and the discharge head 200 discharges the adhesive material AM while moving by a distance of a second length in the second direction DR2, the adhesive material AM applied onto the target substrate may be applied in a rectangular shape having the first length in the first direction DR1 and the second length in the second direction DR2 in plan view.

The first to third moving speeds V1, V2, and V3 may be constant, but are not limited thereto, and may be changed in a process of applying the adhesive material AM.

A thickness of the adhesive material AM applied onto the target substrate may be adjusted by the first moving speed V1 of the discharge head 200. For example, as the first moving speed V1 of the discharge head 200 increases, the thickness of the adhesive material AM applied onto the target substrate may decrease, and as the first moving speed V1 of the discharge head 200 decreases, the thickness of the adhesive material AM applied on the target substrate may increase. That is, when the viscosity of the adhesive material AM is constant and the first moving speed V1 of the discharge head 200 is constant, the thickness of the adhesive material AM applied on the target substrate may be constant for each area.

A moving direction of the light irradiation part 300 may be the same as a moving direction of the discharge head 200. For example, when the discharge head 200 discharges the adhesive material AM while moving in the second direction DR2, the light irradiation part 300 may radiate the light LGT while moving in the second direction DR2 on the other side of the discharge head 200 in the second direction DR2. That is, the light irradiation part 300 may irradiate the light LGT while following the discharge head 200 on the other side of the moving direction of the discharge head 200 in order to temporarily harden the adhesive material AM applied by the discharge head 200.

The second moving speed V2 of the light irradiation part 300 may be substantially the same as the first moving speed V1 of the discharge head 200. In this case, an interval DO between the discharge head 200 and the light irradiation part 300 may be kept to be constant in the process of applying the adhesive material AM. However, the present disclosure is not limited thereto, and the second moving speed V2 of the light irradiation part 300 may be smaller or greater than the first moving speed V1 of the discharge head 200. When the second moving speed V2 of the light irradiating part 300 decreases, an amount of light LGT irradiated for each area may increase, and when the second moving speed V2 of the light irradiating part 300 increases, an amount of light LGT irradiated for each area may decrease.

While the application of the adhesive material AM and the irradiation of the light LGT are performed simultaneously, the interval DO between the light irradiation part 300 and the discharge head 200 may be kept to be constant. For example, a time interval from after the adhesive material AM is discharged from the discharge head 200 and applied onto the target substrate is applied until the light is irradiated may be constant.

The apparatus 10 for manufacturing a display device according to some embodiments may prevent or reduce instances of the adhesive material AM permeating into the through hole TH of the display panel DP by including the second mold 420. In addition, the apparatus 10 for manufacturing a display device may prevent or reduce instances of the adhesive material AM overflowing to the outside of the target substrate in the process of forming the adhesive member ADH by including the first mold 410 and the second mold 420. Accordingly, the adhesive material AM may be applied in a sufficient amount to the outside of the target substrate. Accordingly, the difference in thickness between the central portion and the outer side portion of the adhesive member ADH may be minimized.

Hereinafter, aspects of a method for manufacturing a display device according to some embodiments will be described in more detail.

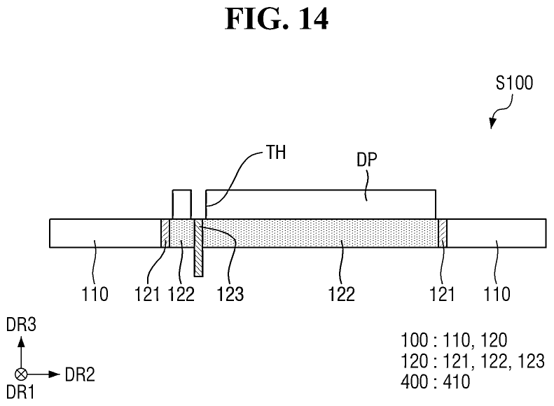

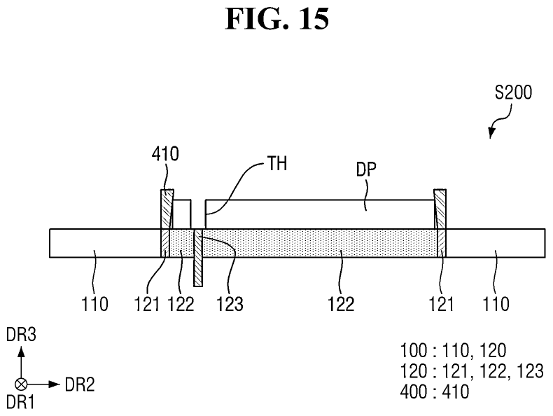

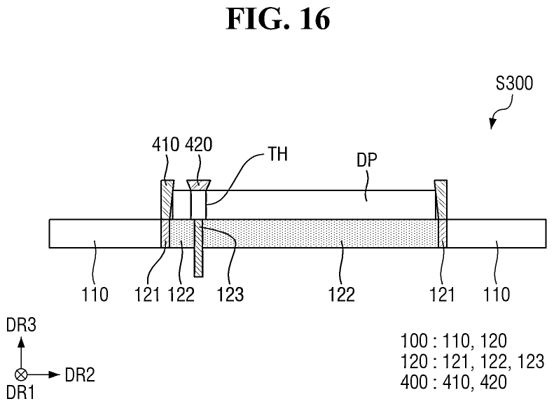

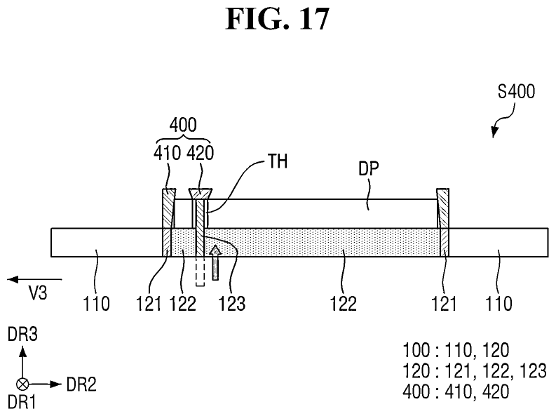

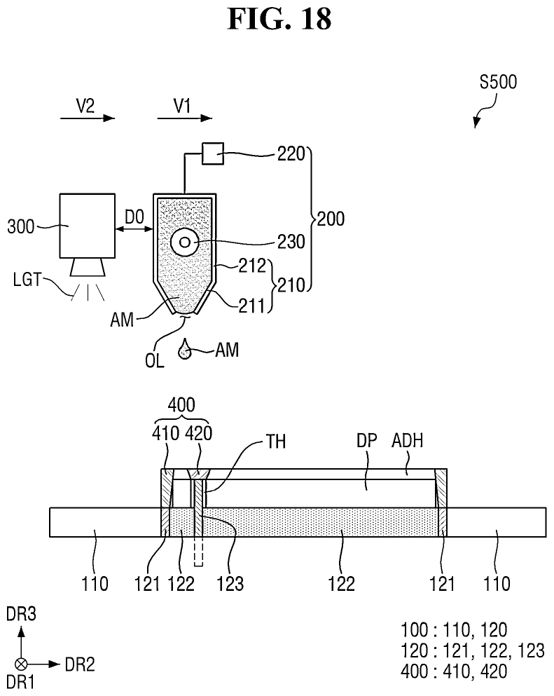

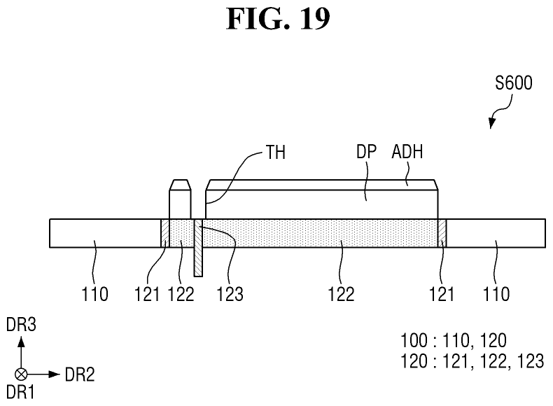

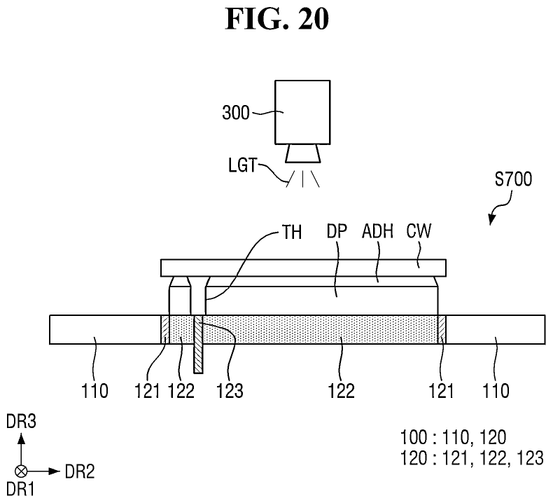

FIG. 13 is a flowchart illustrating aspects of a method for manufacturing a display device according to some embodiments. FIG. 14 is a cross-sectional view illustrating S100 of FIG. 13. FIG. 15 is a cross-sectional view illustrating S200 of FIG. 13. FIG. 16 is a cross-sectional view illustrating S300 of FIG. 13. FIG. 17 is a cross-sectional view illustrating S400 of FIG. 13. FIG. 18 is a cross-sectional view illustrating S500 of FIG. 13. FIG. 19 is a cross-sectional view illustrating S600 of FIG. 13. FIG. 20 is a cross-sectional view illustrating S700 of FIG. 13. Although FIG. 13 illustrates various operations of a method for manufacturing a display device according to some embodiments, embodiments according to the present disclosure are not limited thereto, and according to some embodiments, a method of manufacturing a display device may include additional operations or fewer operations, or the order of operations may vary (unless otherwise stated or implied), without departing from the spirit and scope of embodiments according to the present disclosure.

Referring to FIGS. 13 to 20, a method S1 for manufacturing a display device according to some embodiments may include fixing the display panel on the stage using the second fixing device (S100), fixing the first mold to an outer side of the display panel using the first fixing device (S200), arranged the second mold on the through hole of the display panel (S300), fixing the second mold using the third fixing device (S400), forming the adhesive member by applying the adhesive material using the discharge head and temporarily hardening the applied adhesive material (S500), releasing fixing of the fixing devices and removing the first mold and the second mold (S600), and finally hardening the adhesive member after attaching the cover window onto the adhesive member (S700).

In the fixing of the display panel on the stage using the second fixing device (S100), the display panel DP may be located on the second fixing device 122. The second fixing device 122 may fix the display panel DP using an electrostatic force, a suction force, or the like. In this case, the through hole TH of the display panel DP and the third fixing device 123 may be aligned with each other so as to overlap each other in the third direction DR3.

In the fixing of the first mold to the outer side of the display panel using the first fixing device (S200), the first mold 410 may be arranged to surround the outer side of the display panel DP. The first mold 410 may be located on the first fixing device 121. The first fixing device 121 may fix the first mold 410 using an electrostatic force, a suction force, or the like.

According to some embodiments, when the inner side surface of the first mold 410 is an inclined surface of a reverse-tapered shape, an empty space may be formed between the inner side surface of the first mold 410 and an outer side surface of the display panel DP. Accordingly, the first mold 410 may be easily removed after the adhesive member ADH is formed.

In the forming of the second mold on the through hole of the display panel (S300), the second mold 420 may be located on the through hole TH of the display panel DP. The second mold 420 may overlap the through hole TH of the display panel DP and the third fixing device 123 in the third direction DR3.

Since the length of the lower surface of the second mold 420 is greater than the size of the through hole TH of the display panel DP, the second mold 420 does not fall into the through hole TH, and may be positioned on the through hole TH.

In the fixing of the second mold using the third fixing device (S400), the third fixing device 123 may move toward the second mold 420 in the third direction DR3 by the driving part. The third fixing device 123 may pass through the through hole TH and be located adjacent to the second mold 420.

The third fixing device 123 may fix the second mold 420 using an electrostatic force, a suction force, or the like.

In the forming of the adhesive member by applying the adhesive material using the discharge head and temporarily hardening the applied adhesive material (S500), the discharge head 200 and the light irradiation part 300 may move to one side in the second direction DR2 at the first moving speed V1 and the second moving speed V2, respectively, on the stage 100.

The discharge head 200 may discharge the adhesive material AM while moving in the second direction DR2. The adhesive material AM may be applied onto the display panel DP fixed on one surface of the stage 100.

When the discharge head 200 discharges the adhesive material AM while moving in the second direction DR2, the light irradiation part 300 may radiate the light LGT while moving in the second direction DR2 on the other side of the discharge head 200 in the second direction DR2.

The adhesive material AM irradiated with the light LGT on the display panel DP may be temporarily hardened to form the adhesive member ADH. The adhesive member ADH may be formed to have a shape corresponding to shapes of the first mold 410 and the second mold 420.

In the method S1 for manufacturing a display device according to some embodiments, it may be possible to prevent or reduce instances of the adhesive material AM permeating into the through hole TH by including the second mold 420. In addition, it may be possible to prevent or reduce instances of the adhesive material AM overflowing to the outside of the target substrate by including the first mold 410 and the second mold 420. Accordingly, the adhesive material AM may be applied in a sufficient amount to the outside of the target substrate. Accordingly, the difference in thickness between the central portion and the outer side portion of the adhesive member ADH may be minimized.

In the releasing of the fixing of the fixing devices and the removing of the first mold and the second mold (S600), fixing forces of the first to third fixing devices 121, 122, and 123 may be released. Thereafter, the first to third fixing devices 121, 122, and 123 may be removed from the stage 100 by a separate transfer device.

In the method S1 of manufacturing a display device according to some embodiments, the inner side surface of the first mold 410 and the side surface of the second mold 420 have the inclined surfaces of the reverse-tapered shapes, and thus, the first mold 410 and the second mold 420 may be easily removed.

In the final hardening of the adhesive member after attaching the cover window onto the adhesive member (S700), the cover window CW may be located on the adhesive member ADH. The cover window may be aligned with the display panel DP using a separate alignment device and then located on the adhesive member ADH.

Thereafter, the light irradiation part 300 irradiates the light LGT toward the adhesive member ADH on the cover window, such that the adhesive member ADH may be finally hardened.

Hereinafter, further details of a method for manufacturing a display device according to some embodiments will be described in more detail. In the following embodiments, the same components as those of the above-described embodiments will be denoted by the same reference numerals, and some overlapping description the same or similar components may be omitted or simplified and contents different from those described above will be mainly described.

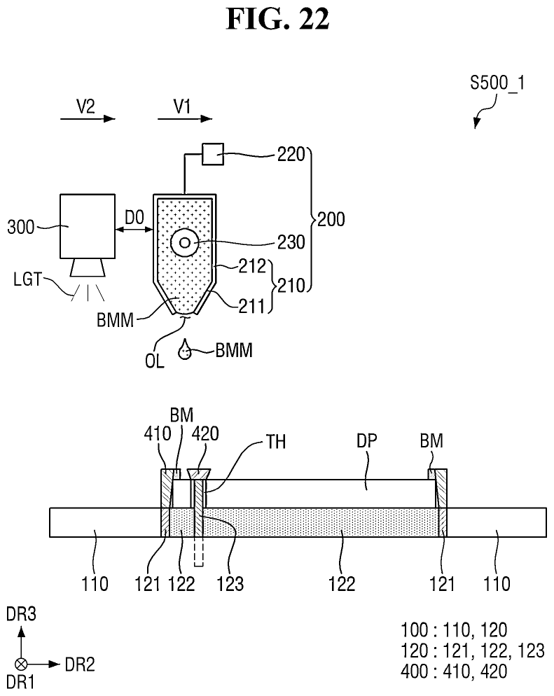

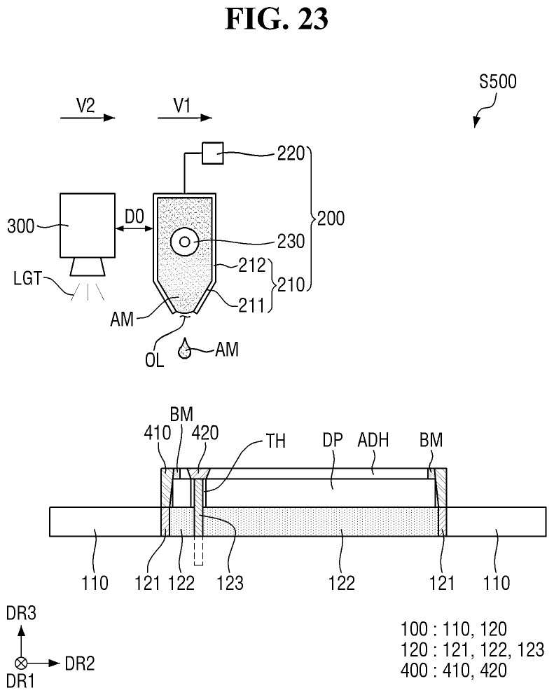

FIG. 21 is a flowchart illustrating a method for manufacturing a display device according to some embodiments. FIG. 22 is a cross-sectional view illustrating S500_1 of FIG. 21. FIG. 23 is a cross-sectional view illustrating S500 of FIG. 21. Although FIG. 21 illustrates various operations of a method for manufacturing a display device according to some embodiments, embodiments according to the present disclosure are not limited thereto, and according to some embodiments, a method of manufacturing a display device may include additional operations or fewer operations, or the order of operations may vary (unless otherwise stated or implied), without departing from the spirit and scope of embodiments according to the present disclosure.

Referring to FIGS. 21 to 23, a method S1_1 for a manufacturing display device according to the present embodiments is different from the method S1 for a manufacturing display device according to an embodiments described with reference to FIG. 13 and the like in that it further includes forming a light blocking member.

For example, the method S1_1 for manufacturing a display device according to the present embodiments may further include forming the light blocking member by applying a light blocking material using the discharge head and hardening the applied light blocking material (S500_1).

The mold 400 and the display panel DP may be fixed using the fixing device 120, and the light blocking material BMM may be applied before the adhesive material AM is applied.

For example, the discharge head 200 and the light irradiation part 300 may move to one side in the second direction DR2 at the first moving speed V1 and the second moving speed V2, respectively, on the stage 100.

The discharge head 200 may discharge the light blocking material BMM while moving in the second direction DR2. The light blocking material BMM may be applied onto a circumference of the display panel DP fixed on one surface of the stage 100. In this case, only a portion of the discharge hole OL is opened, such that the light blocking material BMM may be applied only to the circumference of the display panel DP.

When the discharge head 200 discharges the light blocking material BMM while moving in the second direction DR2, the light irradiation part 300 may radiate the light LGT while moving in the second direction DR2 on the other side of the discharge head 200 in the second direction DR2.

The light blocking material BMM irradiated with the light LGT on the display panel DP may be hardened to form the light blocking member BM.

Thereafter, the adhesive material AM may be applied on the light blocking member BM and the display panel DP to form the adhesive member ADH.

According to the method S1_1 for manufacturing a display device according to some embodiments, the light blocking member BM may be formed along with the process of forming the adhesive member ADH. Accordingly, an additional process for forming a separate light blocking member BM on the cover window CW or forming a separate light blocking member BM along the circumference of the display device DD may not be performed.

In concluding the detailed description, those skilled in the art will appreciate that many variations and modifications can be made to the disclosed embodiments without substantially departing from the spirit and scope of embodiments according to the present disclosure. Therefore, the disclosed embodiments of the present disclosure are used in a generic and descriptive sense only and not for purposes of limitation.

What is claimed is:

1. An apparatus for manufacturing a display device, comprising:
a stage;
a mold on the stage and including a first mold and a second mold surrounded by the first mold;
a discharge head configured to discharge ink;
a light irradiation part configured to irradiate light toward the stage; and
a fixing device configured to fix the mold.

2. The apparatus for manufacturing a display device of claim 1, wherein the second mold is an island-type mold spaced apart from the first mold.

3. The apparatus for manufacturing a display device of claim 1, wherein the mold includes at least one of a silicone-based material or a fluorine-based material.

4. The apparatus for manufacturing a display device of claim 3, wherein the mold includes at least one of polydimethylsiloxane (PDMS) or polytetrafluoroethylene (PTFE).

5. The apparatus for manufacturing a display device of claim 1, wherein
the mold includes at least one of metal, glass, or plastic, and
a mold release agent is applied to at least one side surface of the mold.

6. The apparatus for manufacturing a display device of claim 1, wherein the fixing device includes at least one of a vacuum suction chuck or an electrostatic chuck.

7. The apparatus for manufacturing a display device of claim 6, wherein the mold includes a conductive material.

8. The apparatus for manufacturing a display device of claim 1, wherein the fixing device comprises:
a first fixing device fixing the first mold;
a second fixing device fixing a target substrate; and
a third fixing device fixing the second mold.

9. The apparatus for manufacturing a display device of claim 8, wherein
the target substrate includes a through hole, and
the third fixing device is configured to move inside the through hole.

10. The apparatus for manufacturing a display device of claim 1, wherein at least one of an inner side surface of the first mold or a side surface of the second mold is an inclined surface of a reverse-tapered shape.

11. The apparatus for manufacturing a display device of claim 1, wherein a length of a lower surface of the second mold is greater than or equal to a length of a through hole of a target substrate.

12. The apparatus for manufacturing a display device of claim 1, wherein a height of the first mold is greater than a height of the second mold.

13. A method for manufacturing a display device, comprising:
fixing a display panel on a stage and fixing a first mold to an outer side of the display panel;
arranging a second mold on a through hole of the display panel and fixing the second mold;
forming an adhesive member by applying an adhesive material onto the display panel and temporarily hardening the applied adhesive material; and
removing the first mold and the second mold.

14. The method for manufacturing a display device of claim 13, further comprising forming a light blocking member by applying a light blocking material onto the display panel and hardening the applied light blocking material.

15. The method for manufacturing a display device of claim 14, further comprising applying the light blocking material along an outer side of the display panel.

16. The method for manufacturing a display device of claim 13, wherein fixing the second mold further comprising moving a fixing device inside the through hole to fix the second mold.

17. A display device comprising:
a display panel;
an upper member on the display panel; and
an adhesive member between the display panel and the upper member to attach the display panel and the upper member to each other; wherein
the adhesive member includes a through hole penetrating through at least a portion of the adhesive member, and
a side surface of the through hole is an inclined surface.

18. The display device of claim 17, wherein the through hole has a reverse-tapered shape.

19. The display device of claim 17, wherein the adhesive member further includes a light blocking member arranged along an outer side of the adhesive member.

20. The display device of claim 19, wherein the light blocking member is between the display panel and the upper member.
